(19) United States
(12) Patent Application Publication
(10) Pub. No.: US 2010/0163999 A1
(43) Pub. Date: Jul. 1, 2010

(54) SEMICONDUCTOR ELEMENT AND METHOD OF MANUFACTURING THE SAME

(76) Inventor: Tae-Woong Jeong, Cheongwon-gun (KR)

Correspondence Address: SHERR & VAUGHN, PLLC, 620 HERNDON PARKWAY, SUITE 320, HERNDON, VA, 20170, US

(21) Appl. No.: 12/638,289

(22) Filed: Dec. 15, 2009

(30) Foreign Application Priority Data
Dec. 26, 2008 (KR) 10-2008-0134185

(51) Int. Cl. H01L 27/105; H01L 29/78; H01L 21/8239

(52) U.S. Cl. 257/368; 257/412; 438/275; 257/E29.255; 257/E27.081; 438/302; 257/E21.645

(57) ABSTRACT

A semiconductor element according to embodiments may include: a semiconductor substrate, a first oxide layer pattern formed over the semiconductor substrate, and a first polysilicon pattern formed over the first oxide layer pattern, wherein the substrate, the first oxide layer pattern and the first polysilicon pattern define a recess formed at both sides of the first oxide layer pattern and the first polysilicon pattern. A second polysilicon pattern may be formed over the first oxide layer pattern and the side wall of the first polysilicon pattern in the recess. A second oxide layer pattern, a second nitride layer pattern, and a third oxide layer pattern may be interposed between the first polysilicon pattern and the second polysilicon pattern, and between the second polysilicon pattern and the recess. Embodiments can be operated with lower electrical power in programming and erasing operations by forming a tip portion near a memory gate to increase an electric field at that portion.

The present application claims priority under 35 U.S.C. 119 to Korean Patent Application No. 10-2008-0134185 (filed on Dec. 26, 2008), which is hereby incorporated by reference in its entirety.

### BACKGROUND

In general, nonvolatile memories have the advantage of not losing stored data even if power is switched off. They are used for storing data in PC BIOS, set top boxes, printers, network servers, etc. Recently, they have also used for digital cameras and mobile phones.

In these nonvolatile memories, EEPROM (Electrically Erasable Programmable Read-Only Memory) type flash memory devices may be used. These flash devices have a function of electrically removing data in memory cells collectively or sector by sector. They do this by increasing the threshold voltage by creating channel hot electrons in drains to accumulate electrons in floating gates, thereby programming a data cell. In contrast, the erasing operation of the flash memory devices generates high voltage between a source/substrate and a floating gate, to decrease the threshold voltage of a cell transistor, by emitting the electrons accumulated in the floating gate.

With rapid progress towards higher integration in recent years, there has been strong pressure to reduce the cell size. However, floating gate type cells require high voltage to erase a cell, and have difficulty in ensuring a margin in a process, such as tunnel definition, such that it is almost impossible to further reduce the size. In this reason, researches on nonvolatile memory elements that replace the floating gate type cells.

### SUMMARY

Embodiments relate to a semiconductor element that has a cell structure that is efficient in electric power consumption in a nonvolatile memory element, and a method of manufacturing the semiconductor element. Embodiments relate to a semiconductor element in which the thickness of a select gate, which functions as a fence, can be reduced as much as the depth of a recess, by forming a memory gate in the recess.

A semiconductor element according to embodiments may include a semiconductor substrate, a first oxide layer pattern formed over the semiconductor substrate, and a first polysilicon pattern formed over the first oxide layer pattern, wherein the substrate, the first oxide layer pattern and the first polysilicon pattern define a recess formed at both sides of the first oxide layer pattern and the first polysilicon pattern. A second polysilicon pattern may be formed over the first oxide layer pattern and the side wall of the first polysilicon pattern in the recess. A second oxide layer pattern, a second nitride layer pattern, and a third oxide layer pattern may be interposed between the first polysilicon pattern and the second polysilicon pattern, and between the second polysilicon pattern and the recess.

A method of manufacturing a semiconductor element according to embodiments may include: forming a first oxide layer over a semiconductor substrate; forming a first polysilicon layer over the first oxide layer; forming a first oxide layer pattern, a first polysilicon pattern, and a recess of the semiconductor substrate, by etching portions of the first polysilicon layer, the first oxide layer, and the semiconductor substrate; sequentially stacking a second oxide layer, a first nitride layer, and a third oxide layer over a surface of the semiconductor substrate including the recess and the first polysilicon pattern; forming a second polysilicon layer over the third oxide layer; forming a second polysilicon pattern, from the polysilicon layer, over side walls of the recess; removing one of the second polysilicon patterns formed at both side walls; and forming a second oxide layer pattern, a second nitride layer pattern, and a third oxide layer pattern, which are interposed between the first polysilicon pattern and the second polysilicon pattern and between the second polysilicon pattern and the recess, by selectively removing the third oxide layer, the first nitride layer, and the second oxide layer.

### DRAWINGS

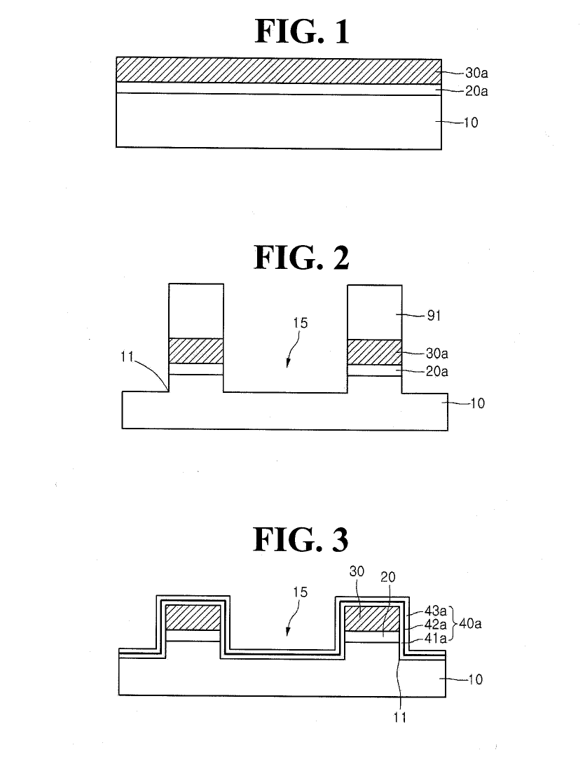

Example FIGS. 1 to 8 are cross-sectional views illustrating a method of manufacturing a semiconductor element according to embodiments.

### DESCRIPTION

A semiconductor element and a method of manufacturing the semiconductor element, according to embodiments, are described in detail with reference to the accompanying drawings. Example FIGS. 1 to 8 are cross-sectional views illustrating a method of manufacturing a semiconductor element according to embodiments.

An active area may be defined by forming an element isolation film over a semiconductor substrate 10. A well region may be formed by applying an ion injection process to the semiconductor substrate 10.

As shown in example FIG. 1, a first oxide layer 20a may be formed over the semiconductor substrate 10. A first polysilicon layer 30a may be formed over the first oxide layer 20a. The first oxide layer 20a may be formed by applying a method including, for example, one of a heat treatment process, a CVD (Chemical Vapor Deposition) process, and ALD (Atomic Layer Deposition), to the semiconductor substrate 10.

As shown in example FIG. 2, a first photoresist pattern 91 may be formed over the first polysilicon layer 30a. A first oxide layer pattern 20 and a first polysilicon pattern 30 over the first oxide layer pattern 20 may be formed by etching the first polysilicon layer 30a and the first oxide layer 20a, using the first photoresist pattern 91 as a mask. In the etching process, a recess 15 may be formed on the semiconductor substrate 10 by etching the first oxide layer pattern 20 and the semiconductor substrate 10 exposed by the first polysilicon pattern 30, to a predetermined depth. That is, the recess 15 may be formed at both sides of the first polysilicon pattern 30, to a predetermined depth from the upper surface of the semiconductor substrate 10.

A tip portion 11 may be formed toward the inside of the semiconductor substrate 10 on the bottom of the recess 15 formed on the semiconductor substrate 10. The recess 15 may be formed in a depth of 500 Å˜1,000 Å. The first polysilicon pattern 30 may be formed in a depth of 1,500 Å˜2,500 Å by the height ensured by the recess 15.

Further, a memory gate that will be formed later over the side walls of the first polysilicon pattern 30 in the recess 15 may be formed with a height ensured by the recess 15, and a depth of 2,500 Å˜3,500 Å from the side walls of the first oxide layer pattern 20 and the first polysilicon pattern 30. In this configuration, the first polysilicon pattern 30 functions as a select gate.

As shown in example FIG. 3, an ONO layer 40a formed by sequentially stacking a second oxide layer 41a, a first nitride layer 42a, and a third oxide layer 43a of the front surface of the semiconductor substrate 10 where the first oxide layer pattern 20 and the first polysilicon pattern 30 are formed. The second oxide layer 41 a may be formed in a depth of 10 Å˜100 Å.

The first nitride layer 42a may be formed, for example, by applying one of a CVD (Chemical Vapor Deposition) process and an ALD (Atomic Layer Deposition) process to the first oxide layer. The first nitride layer 42a may be formed in a depth of 10 Å˜100 Å.

The third oxide layer 43a may be formed by applying one of a CVD (Chemical Vapor Deposition) process and an ALD (Atomic Layer Deposition) process to the first nitride layer. The second and third oxide layers 41a, 43a may be formed in a depth of 10 Å˜100 Å. The second oxide layer 41a, first nitride layer 42a, and third oxide layer 43a may be formed along the inner wall of the recess 15, covering the first oxide layer pattern 20 and the first polysilicon pattern 30.

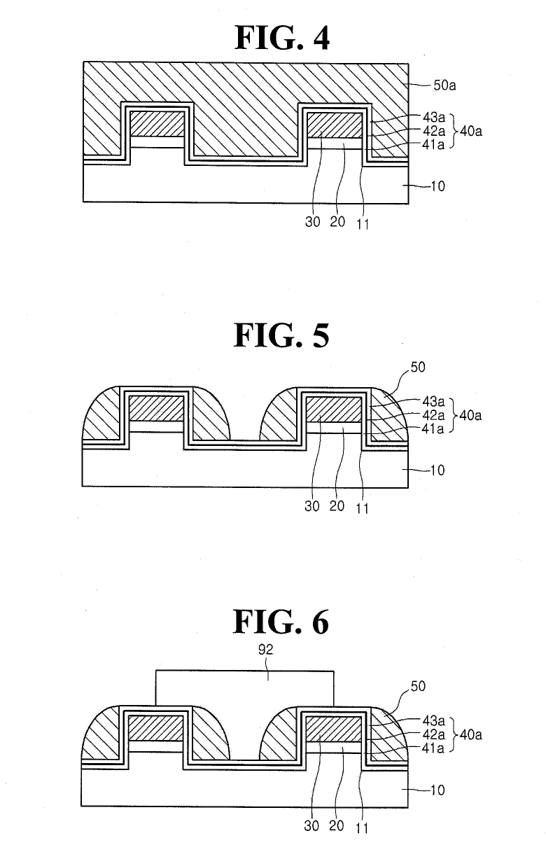

Subsequently, as shown in example FIG. 4, a second polysilicon layer 50a may be formed over the third oxide layer 43a. As shown in example FIG. 5, a second polysilicon pattern 50 may be formed in the shape of a spacer over the third oxide layer 43a at both side walls of the first polysilicon pattern 30 by anisotropic-etching the second polysilicon layer 50a.

The second polysilicon pattern 50 may be formed over the third oxide layer 43a formed on the recess 15, and uses as a fence the side wall of the semiconductor substrate 10, the side wall of the first oxide layer pattern 20, and the side wall of the first polysilicon pattern 30, which relatively protrude by the recess 15. Therefore, the second polysilicon pattern 50 may have a height defined from the third oxide layer 43a on the recess 15 to the upper surface of the first polysilicon pattern 30. The second polysilicon pattern 50 may have a height of 2,500 Å˜3,500 Å.

Subsequently, as shown in example FIG. 6, a second photoresist pattern 92 may be formed which covers one of the second polysilicon patterns 50 formed at both side walls of the first polysilicon patterns 30. The second photoresist pattern 92 may cover a portion of the upper surface of the first polysilicon pattern 30. In adjacent cells, the second photoresist pattern 92 may be formed over the second polysilicon pattern 50 disposed inside the first polysilicon patterns 30 facing each other.

Subsequently, the exposed second polysilicon pattern 50 may be etched using the second photoresist pattern 92 as a mask. Next, the second photoresist pattern 92 may be removed. Subsequently, a gate space may be formed at one side of each of the first polysilicon pattern 30 and the second polysilicon pattern 50 by forming and anisotropic-etching a dielectric layer over the first polysilicon pattern 30 and the second polysilicon pattern 50.

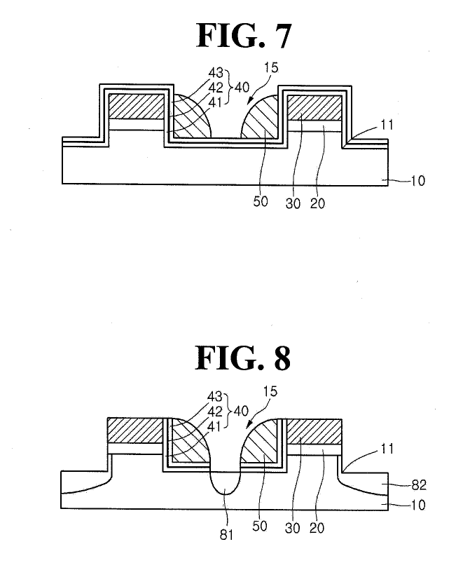

As shown in example FIG. 7, an ONO pattern 40 including a second oxide layer pattern 41, a first nitride layer pattern 42, and a third oxide layer pattern 43 may be formed under the second polysilicon pattern by removing the second oxide layer 41a, first nitride layer 42a, and third oxide layer 43a.

As a result, the first oxide layer pattern 20 is formed over the semiconductor substrate 10 and the first polysilicon pattern 30 is formed over the first oxide pattern 20. The second oxide layer pattern 41, first nitride layer pattern 42, and third oxide layer pattern 43 may be formed at one side of the first polysilicon pattern 30 and the first oxide layer pattern 20, over the side wall in the recess 15 of the semiconductor substrate 10, and over a portion of the bottom in the recess 15. A second polysilicon pattern 50 may be formed over the third oxide layer pattern 43 at the side wall of the first polysilicon pattern 30.

Therefore, the ONO pattern 40 may be formed between the first polysilicon pattern 30 and the second polysilicon pattern 50, and between the second polysilicon pattern 50 and the semiconductor substrate 10. The first oxide layer pattern 20 may be formed between the first polysilicon pattern 30 and the semiconductor substrate 10, such that the first polysilicon pattern 30 operates as a select gate and the second polysilicon pattern 50 operates as a memory gate.

The upper surface of the first polysilicon pattern 30 and a side of the first polysilicon pattern 30 may be exposed by a process of removing portions of the second polysilicon pattern 50 and the ONO pattern 40. Further, as the recess 15 at the side with the second polysilicon pattern 50 removed, on both sides of the first polysilicon pattern 30, may be exposed, the sides and bottom in the recess 15 may be exposed.

As shown in example FIG. 8, a first dopant region 81 and a second dopant region 82 may be formed by injecting dopant into the semiconductor substrate 10 which is exposed by the first polysilicon pattern 30 and the second polysilicon pattern 50. The first dopant region 81 may be a region that is jointly operated by adjacent cells. The first dopant region 81 may be formed by applying an ion injection process to the semiconductor substrate 10 near the second polysilicon pattern 50.

The second dopant region 82 may be formed by applying an ion injection process to the recess 15 of the semiconductor substrate 10 near the first polysilicon pattern 30. The second dopant region 82 may be formed on the side and bottom of the recess 15 and may be formed by a tilt ion injection process.

Since the tip portion 11 is formed at the bottom by the recess 15 of the semiconductor substrate 10, under the second polysilicon pattern 50, the electric field increases in this portion. Accordingly, programming and erasing operations can be performed by small electric power, such that it is efficient in electric power consumption in a nonvolatile memory.

A hot carrier formed under the first polysilicon pattern 30 may have higher electric fields at the tip portion 11, and trap electrons at the first nitride layer 42, such that the hot carrier may be more efficiently generated in programming and erasing. Accordingly, it may be possible to decrease the voltage that is applied to the second polysilicon pattern 50 that operates as the memory gate.

The tip portion 11 may be formed on the recess 15 of the semiconductor substrate 10, by the edge of the bottom. The tip of the tip portion 11 may be formed toward the inside of the semiconductor substrate 10. A metal layer may be formed over the surface of the semiconductor substrate 10 after the ion injection process. A process for forming a silicide may be performed by applying heat treatment to the metal layer.

According to embodiments, it may be possible to reduce the thickness of the select gate functioning as a fence to the depth of the recess by forming the memory gate in the recess. Excellent process margin can be thereby achieved, and the characteristics of the elements are generally uniform. Excellent reliability of the elements can be achieved by forming the memory gate, using a self-alignment method.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a semiconductor substrate;
a first oxide layer pattern formed over the semiconductor substrate;
a first polysilicon pattern formed over the first oxide layer pattern, wherein the substrate, the first oxide layer pattern and the first polysilicon pattern define a recess formed at both sides of the first oxide layer pattern and the first polysilicon pattern;
a second polysilicon pattern formed over the first oxide layer pattern and the side wall of the first polysilicon pattern in the recess; and
a second oxide layer pattern, a second nitride layer pattern, and a third oxide layer pattern interposed between the first polysilicon pattern and the second polysilicon pattern, and are further interposed between the second polysilicon pattern and the recess.

2. The apparatus of claim 1, including a first dopant region formed over the semiconductor substrate in the bottom of the recess, and at a side of the second polysilicon pattern.

3. The apparatus of claim 1, including a second dopant region formed on the side and the bottom of the first polysilicon pattern in the recess.

4. The apparatus of claim 1, wherein the edge of the bottom of the recess is formed under the second polysilicon pattern.

5. The apparatus of claim 1, wherein the depth of the recess is between 500 Å and 1,000 Å.

6. The apparatus of claim 1, wherein the thickness of the first polysilicon pattern is between 1,500 Å and 2,500 Å.

7. The apparatus of claim 1, wherein the height of the second polysilicon pattern is between 2,500 Å and 3,500 Å.

8. The apparatus of claim 1, wherein the first polysilicon pattern is a select gate.

9. The apparatus of claim 1, wherein the second polysilicon pattern is a memory gate.

10. A method comprising:
forming a first oxide layer over a semiconductor substrate;
forming a first polysilicon layer over the first oxide layer;
forming a first oxide layer pattern, a first polysilicon pattern, and a recess of the semiconductor substrate, by etching portions of the first polysilicon layer, the first oxide layer, and the semiconductor substrate;
sequentially stacking a second oxide layer, a first nitride layer, and a third oxide layer over a surface of the semiconductor substrate including the recess and the first polysilicon pattern;
forming a second polysilicon layer over the third oxide layer;
forming a second polysilicon pattern, from the polysilicon layer, over side walls of the recess;
removing one of the second polysilicon patterns formed at both side walls; and
forming a second oxide layer pattern, a second nitride layer pattern, and a third oxide layer pattern, which are interposed between the first polysilicon pattern and the second polysilicon pattern and between the second polysilicon pattern and the recess, by selectively removing the third oxide layer, the first nitride layer, and the second oxide layer.

11. The method of claim 10, including forming a first dopant region on the bottom of the recess of the semiconductor substrate at a side of the second polysilicon pattern.

12. The method of claim 11, wherein the first dopant region is formed using an ion injection process.

13. The method of claim 11, including forming a second dopant region on the side and the bottom in the recess at a side of the first polysilicon pattern.

14. The method of claim 13, wherein the second dopant region is formed using an ion injection process.

15. The method of claim 13, wherein the second dopant region is formed by a tilt ion injection process.

16. The method of claim 10, wherein the depth of the recess is between 500 Å and 1,000 Å.

17. The method of claim 10, wherein the thickness of the first polysilicon pattern is between 1,500 Å and 2,500 Å.

18. The method of claim 10, wherein the height of the second polysilicon pattern is between 2,500 Å and 3,500 Å.

19. The method of claim 10, wherein the second polysilicon pattern is formed by anisotropic etching.

20. The method of claim 10, wherein the second oxide layer, the first nitride layer, and the third oxide layer are each formed with a thickness of between 10 Å and 100 Å.
